(19) United States
(12) Patent Application Publication
(10) Pub. No.: US 2018/0278866 A1
(43) Pub. Date: Sep. 27, 2018

(54) MATRIX SENSOR WITH LOGARITHMIC RESPONSE AND EXTENDED TEMPERATURE OPERATING RANGE

(71) Applicant: NEW IMAGING TECHNOLOGIES, Verrieres Le Buisson (FR)

(72) Inventor: Yang NI, Palaiseau (FR)

(21) Appl. No.: 15/542,113

(22) PCT Filed: Jan. 4, 2016
(86) PCT No.: PCT/EP2016/050027

§ 371 Date: Jul. 7, 2017

(30) Foreign Application Priority Data
Jan. 9, 2015 (FR) 1550177

(51) Int. Cl. H04N 5/361; H01L 27/146; H04N 5/363; H04N 5/235; H04N 9/04; H04N 5/359

(52) U.S. Cl. CPC H04N 5/361; H01L 27/14609; H01L 27/14654; H04N 5/3591; H04N 5/2352; H04N 9/045; H04N 5/363

(57) ABSTRACT

A matrix sensor with logarithmic response and extended temperature operating range, including a plurality of active pixels each defined by a photodiode (PD) operating in solar cell mode, the photodiode being formed by a semiconductor junction in a substrate (11), a reverse-biased junction (20) being present at a distance (d), from the junction of the photodiode, that is less than the diffusion length of the charges in the substrate, the reverse-biased junction (20) being produced by a diffusion to a depth (p) greater than that (p′) used in the formation of the source or drain of transistors of the sensor, adjacent to the photodiode.

The present invention relates to optical sensors and more particularly to optical sensors using complementary metal-oxide semiconductor (CMOS) integration technology.

CMOS integration technology allows chips to be produced for monolithic video cameras of good resolution and reasonable image quality. These monolithic video cameras are mainly intended for portable devices such as cell phones, digital cameras or laptops. The images taken by these video cameras essentially serve for viewing on a screen or on the Internet.

The very economical nature of this type of video camera has led to steadily increasing interest therein for multiple applications within video-assisted systems such as automobile smart airbags, lateral and longitudinal control of an automobile on a highway, or video surveillance of controlled zones, etc.

A first difficulty encountered in the use of such a video camera resides in the extent of the variation in illuminance in a given scene. This variation may easily exceed 120 dB between highly illuminated zones and poorly illuminated zones. Since conventional CCD or CMOS video cameras have a linear response, they cannot easily accommodate such a variation and often produce images that are completely or partially saturated, leading to the loss of relevant information and an unstable vision system.

A second difficulty resides in the amplitude and rate of variation in brightness in a dynamic scene. The mechanisms for automatically controlling exposure of conventional video cameras cannot adequately respond thereto and therefore complete or partial saturation, which is extremely prejudicial to the correct operation of the system, results.

Many methods propose to solve these problems by creating active pixel structures possessing a dynamic operating range that is increased by virtue of a nonlinear photoelectric response exhibiting a lower sensitivity in case of high brightness.

Thus, patent application EP 1354360 describes an active pixel structure with a logarithmic response, based on the use of a photodiode in photovoltaic regime (also called solar-cell mode). The photodiode may be formed from a p-n junction formed from an n-diffusion in a p-type substrate. In photovoltaic operation, this photodiode generates a negative open-circuit voltage the absolute value of which is proportional to the logarithm of the illuminance falling on the photodiode. A reset transistor allows a short-circuit to be created in this photodiode in order to simulate darkness in the presence of normal illumination. Read-out of a differential between the open-circuit and short-circuit voltages generated by the photodiode allows fixed pattern noise (FPN) to be suppressed in the read chain and thus a clean image to be obtained.

Patents FR 2 920 590 and FR 2 943 178 describe a number of improvements to sensors the pixels of which use photodiodes operating in solar-cell mode.

Patent application WO 2014/064274 discloses an active-pixel structure including a first photodiode operating in photovoltaic mode and a second photodiode operating in integration mode, in order to accumulate charge carriers generated in the first photodiode.

Patent application US 2002/0024058 discloses a photodetector circuit including avalanche photodiodes.

All these embodiments achieve a good performance in terms of image capture but drift with operating temperature. This temperature drift adds a constant but quite uniform offset voltage to the image output from the sensor. It is not disadvantageous for simple observation applications, but becomes so for applications—such as optical metrology, thermography or color imaging—in which the absolute response of the sensor is important.

One of the aims of the present invention is thus to provide an optical sensor having a very large dynamic operating range and a photoelectric response that is stable with temperature.

Moreover, a temperature-related voltage offset is conventionally corrected with a reference signal generated by a pixel placed in the dark. For greater stability, a group of pixels placed in the dark is used and their responses are averaged in order to obtain a stable reference level.

Next, on each read-out, this reference level is subtracted from the signal read from the photodiode exposed to light, in order to obtain a response that is stable with temperature.

This method is used in a good number of known image sensors to stabilize their response either with respect to temperature or with respect to dispersions in component parameters.

However, it is not completely effective with a logarithmic-response pixel using a photodiode in solar-cell mode for a number of reasons.

Firstly, it is difficult to mask light over a very large operating range. The metal layers used for this purpose inevitably contain microcracks that make these layers permeable to light, above all at high light intensities.

Furthermore, multiple-layer solutions are not as effective as would be desired because of optical resonance between the metal layers, which means that absorption adds rather than multiplying. For example, stacking two metal layers merely doubles the attenuation.

Lastly, the leakage of light via the edges of metal masking layers generates an unacceptable variation in the dark level, because a logarithmic-response pixel is very sensitive to a low light intensity.

There is therefore also a need to remedy this drawback.

Conventional CMOS optical sensors, i.e. those the pixels of which include photodiodes not operating in solar-cell mode, are very sensitive to over exposure, contrary to the sensors to which the invention relates, which are not as sensitive to over exposure because of their logarithmic response.

As described in the publication WO 2014/131704 A1 in particular, it is known to combat this over-exposure effect with a diffusion adjacent to the photodiode, this diffusion for example being formed with the gate of a reset transistor of the photodiode. However, this publication makes absolutely no mention of the fact that such a diffusion may be used to advantageous effect with respect to the temperature dependency of the operation of a logarithmic-response pixel.

The invention aims to remedy all or some of the aforementioned drawbacks and one of its subjects, according to one of its aspects, is a logarithmic-response matrix-array sensor having an extended temperature operating range, said sensor including a plurality of active pixels each defined by a photodiode operating in solar-cell mode, the photodiode being formed by a semiconductor junction in a substrate, a reverse-biased junction being present at a distance from the junction of the photodiode smaller than the diffusion length of charge carriers in the substrate, this junction preferably being formed by diffusion in the substrate to a depth larger than that used in the formation of the source or drain of those transistors of the sensor which are adjacent to the photodiode.

Thus, the reverse-biased junction according to the invention is different from the diffusion necessary to form the source or drain of transistors neighboring the photodiode.

Each diffusion may be local and discrete and associated with only one respective photodiode.

However, the reverse-biased junction is preferably obtained by a diffusion that is common to a plurality of photodiodes and that either extends thereunder or that extends thereunder and surrounds at least two sides of each photodiode.

The advantage of a diffusion common to a plurality of photodiodes is to allow a higher photodiode implantation density, and the advantage of a diffusion that encircles each photodiode is to allow a better anti-blooming effect to be obtained, allowing dynamic operating range to be further increased.

The diffusion depth corresponds to the lower limit of the diffusion, measured from the surface.

Whereas the diffusions used to form the source or drain of transistors are preferably confined to near-surface in order to prevent parasitic currents from preventing good gate control, the diffusion used to form the reverse-biased junction is preferably deeper, so that it is able to play an active role in the temperature behavior of the logarithmic pixel.

An advantageous configuration is to place the junction of the photodiode in solar-cell mode in a well that is reverse-biased with respect to the substrate. This arrangement completely suppresses crosstalk due to the blooming effect between neighboring photodiodes.

By virtue of the reverse-biased diffusion located nearby, the response of the photodiode according to the invention is subject to a temperature effect that may be summed up as a simple shift as temperature increases. The invention allows a logarithmic response to be obtained in a wide temperature range, in particular between −50° C. and 100° C.

Preferably, the sensor includes a capacitance for injecting a charge into the photodiode in order to forward bias it before read-out of a voltage representative of the illumination received by the photodiode. Such an injection allows a logarithmic response to be obtained at even lower temperatures.

Also preferably, the sensor includes reference pixels used to generate a reference voltage, serving to compensate for a temperature-related shift in the response of the active pixels, this or these reference pixels being masked from incident light and placed virtually under given non-zero illumination conditions by injecting a current into the junction of the photodiode of the reference pixel.

This current may be injected into the photodiode of a reference pixel through an electrical resistance that is connected to a voltage source that generates a current in the same direction as the photoelectric current generated by the photodiode under the effect of its illumination. As a variant, this current may be injected into the photodiode of a reference pixel through a capacitance connected to a ramp voltage source that generates a current in the same direction as the photoelectric current generated by the photodiode.

Thus, according to this aspect of the invention, instead of creating a dark reference level, a reference level corresponding to a certain level of illumination is created by electrically simulating this illumination in the one or more reference pixels. Thus, the drawbacks recalled in the preamble, regarding the use of a dark reference level, are avoided because the influence on the reference signal of parasitic light is less at a high illumination level.

The substrate may be p-type semiconductor, in particular p-type silicon, and the photodiode may include an n+-type region.

The reverse-biased junction may be achieved via an n⁺-type region. The n⁺-type region of the reverse-biased junction is advantageously defined by an n-doped well of a PMOS transistor for reading the voltage of the photodiode.

The sensor may include, for each pixel, a transistor for resetting the photodiode, applying, when in the on state, a predefined bias voltage to the photodiode.

The capacitance for injecting charge into the photodiode, in order to forward bias it before the exposure, may be a parasitic gate-drain capacitance of this reset transistor, which it is sought to develop, or as a variant a specifically produced capacitance.

The initial bias voltage of the photodiode obtained by virtue of this injection of charge may be comprised between 0.1 and 0.2 V.

Yet another subject of the invention is a method for operating a sensor according to the invention, i.e. a sensor such as defined above, including resetting the photodiode by closing a reset transistor and injecting a charge into the photodiode in order to forward bias it at the start of the phase of exposure to the light received by the photodiode and obtaining a logarithmic response in an extended-temperature operating range.

This temperature range may encompass at least the range extending from −15° C. to 60° C. and better still the range extending from −50° C. to 100° C.

Preferably, the voltage of the photodiode of an active pixel is corrected by the voltage read from a reference pixel, for example by subtraction, in order to generate a signal representative of the illumination received by the active pixel and independent of the temperature in the operating range.

The aforementioned ramp, serving to generate the current simulating a certain level of illumination of the reference pixel, may consist of the falling front of a control signal of the reset transistor.

The invention will possibly be better understood on reading the following detailed description of nonlimiting example embodiments thereof and on examining the appended drawing, in which:

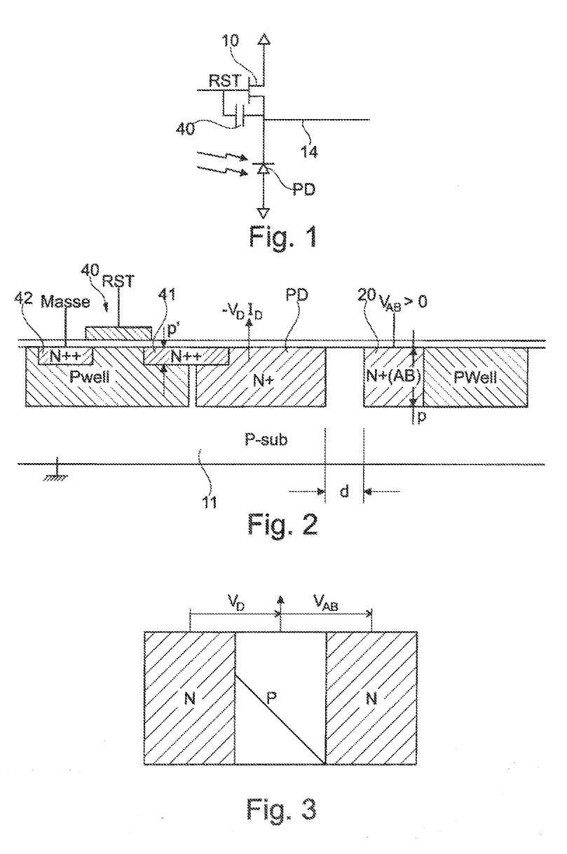

FIG. 1 is an equivalent circuit diagram of a pixel of a sensor according to the invention;

FIG. 2 schematically and partially shows the CMOS structure of a pixel;

FIG. 3 illustrates the charge profile in the substrate of the photodiode;

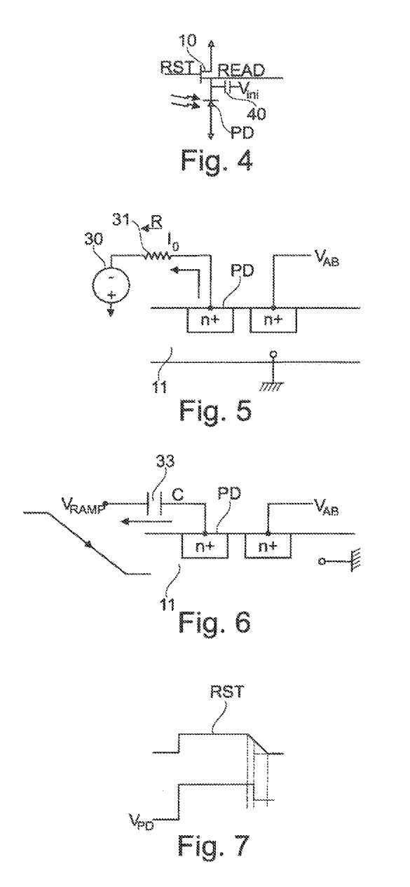

FIG. 4 is a diagram analogous to that of FIG. 1, of a variant embodiment of the pixel;

FIG. 5 illustrates the generation of a current simulating exposure in a reference pixel;

FIG. 6 is a view analogous to FIG. 5 of a variant embodiment;

FIG. 7 is a timing diagram illustrating a way of generating the charge to be injected by the ramp;

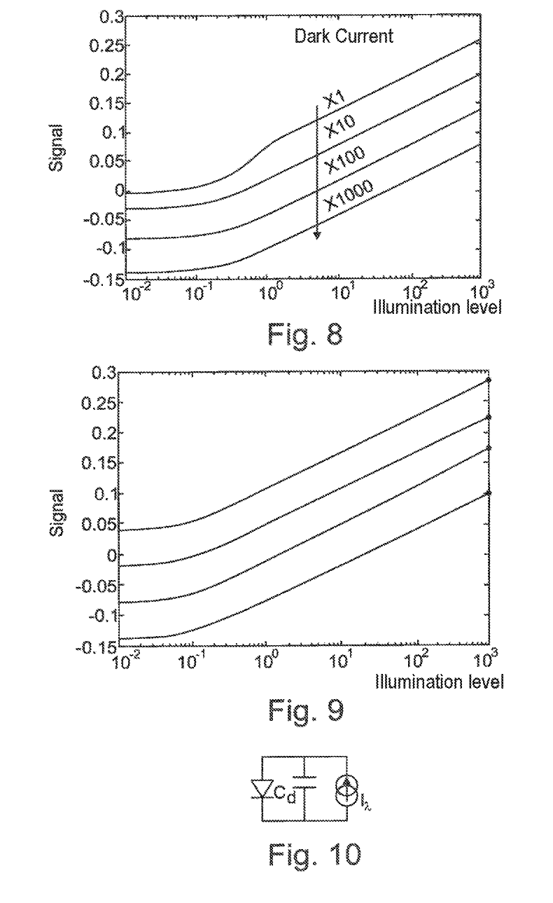

FIG. 8 shows the variation of the voltage generated by a pixel as a function of the illumination level, in the absence of injection of charge prior to the read-out of the voltage of the photodiode in the anode-cathode direction;

FIG. 9 shows the voltage generated by a pixel according to the invention in the anode-cathode direction, after injection of charge prior to the start of the exposure of the photodiode, as a function of the illumination level; and

FIG. 10 is a schematic representation of a simplified equivalent circuit of the photodiode; and

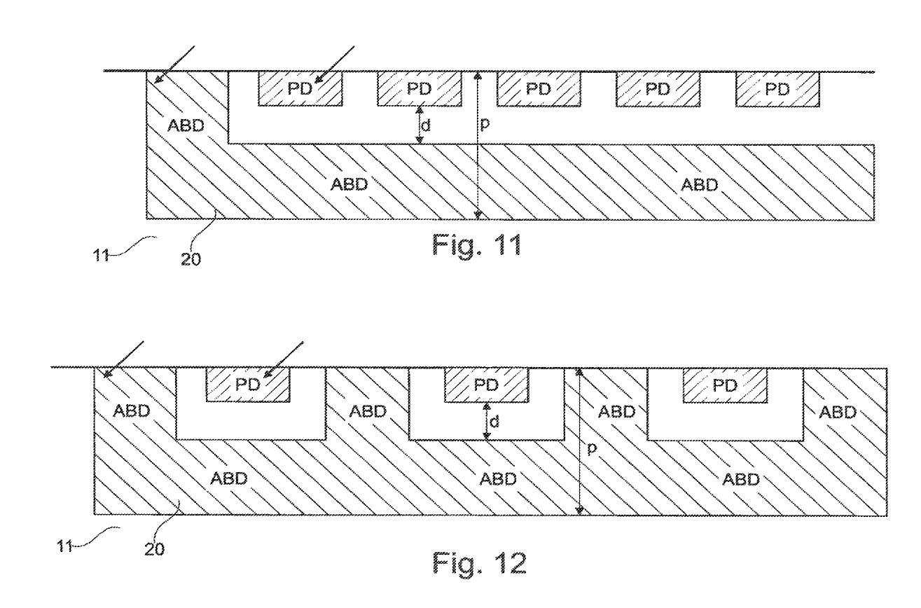

FIGS. 11 and 12 schematically show variant embodiments of the sensor.

FIG. 1 schematically and partially shows the electronic circuit of a pixel of an optical sensor according to the invention. This pixel forms part of a detector matrix-array including rows and columns of pixels. Each pixel includes a photodiode PD associated with electronics for reading its voltage, which have not been described in detail; examples of circuits for reading photodiodes in solar-sell mode are for example described in patent FR 2 943 178.

The open-circuit voltage of the photodiode PD in solar-cell mode is sampled at 14 by way of output signal. The photodiode is reset (reset operation) after each read cycle by closing a reset transistor 10 that is controlled by a signal RST, as illustrated in FIG. 1, this transistor applying, when closed, a predefined potential to the terminals of the photodiode.

The photodiode PD may be formed by diffusing n dopants into a p-type substrate 11, as illustrated in FIG. 2, using a conventional CMOS integration technology.

The reset operation allows the photoelectric charge stored on the cathode of the photodiode PD to be emptied, but that stored in the substrate must also be empty.

If the density of pixels in the matrix array of the sensor is low, the charge carriers that make up this charge recombine naturally in the substrate. In contrast, if the pixel matrix-array is dense, this being the case in a sensor according to the invention, these charge carriers must be absorbed expressly.

According to the invention, a reverse-biased junction 20 is created in the substrate 11 at a distance d from the photodiode PD smaller than the diffusion length.

The reset transistor 40 includes junctions 41, 42 the n⁺⁺ regions of which extend to a depth p′ smaller than the depth p of the region 20.

Diffusion length characterizes the distance that minority carriers travel in the substrate before recombining. This distance is commonly called Lp in a p-type substrate, as in the considered example. Lp is for example determined as described in “Physics of Semiconductor Devices”, which book was written by S.M. Sze and published by John Wilet & Sons in 1981, ISBN 0-471-05661-8. Lp is for example comprised between 50 μm and 200 μm in a standard substrate for fabrication of CMOS circuits.

The junction 20 may be created with an n⁺-type region, for example the well N_{well} of at least one PMOS transistor used for read-out of the voltage of the photodiode PD, this transistor not being shown in the drawing for the sake of clarity. Examples of read circuits using PMOS transistors are described in FR 2 943 178.

As a variant, in particular when the read circuit used includes, as described in FR 2 920 590, only NMOS transistors, an n-diffusion may be formed in proximity to the photodiode PD. This n-diffusion may form part of the diffusions forming the active or passive components of the pixel, for example the sources or drains of the NMOS transistors.

In the case of a p-type substrate 11 made of silicon, the n⁺ region of the photodiode is for example formed either by diffusion, or by ion implantation, with arsenic or phosphorus, and the same process is used for the reverse-biased n⁺ region.

For a single photodiode in a substrate, equation (1) below governs the relationship between the current I_{D} and the voltage V_{D} of said photodiode.

$${I}_{D} = {I}_{S} {e}^{\frac{{V}_{D}}{{V}_{t}}} - {I}_{S} \qquad ( 1 )$$

Vₜ is the voltage of thermal origin, typically about 26 mV at 20° C. and I_{S} is the saturation current of the junction of the photodiode.

The static open-circuit voltage of the illuminated diode, in solar-cell mode, is given by equation (2) below. I_{λ} is the photoelectric current.

$${V}_{D} = {V}_{t} log ( \frac{{I}_{λ} + {I}_{S}}{{I}_{S}} ) \qquad ( 2 )$$

It may be seen that the voltage across the photodiode no longer varies logarithmically when Is becomes large. It will be noted that Is doubles about every 7° C. in silicon.

With an n-doped region formed by the junction 20 in proximity to the photodiode, i.e. at a distance smaller than the diffusion length Lp, the variation in the voltage across the photodiode is influenced by the bias of this n-doped region.

A model based on the diffusion of minority charge carriers between the photodiode and the nearby n-doped region allows the equation relating the voltage and current of the photodiode to be derived.

As FIG. 3 shows, an n-diffusion reverse biased by a voltage VA (called the over-exposure protection voltage) in proximity to a photodiode in solar-cell mode changes the profile of the minority carriers (namely electrons in this precise case) in the p-type zone. Thus, the charge injected into the substrate 11 by the photodiode diffuses toward the n-doped region, which is reverse biased, according to a diffusion law.

In a substrate intended for the fabrication of an image sensor, crystal quality is excellent. Therefore, for a small distance between the n-type regions with respect to the diffusion length, the distribution of minority carriers is substantially triangular.

It is possible to derive a current-voltage relationship for this photodiode:

$${I}_{D} = {I}_{S} {e}^{\frac{{V}_{D}}{{V}_{t}}} - {I}_{S} {e}^{- \frac{{V}_{AB}}{Vt}} \qquad ( 3 )$$

From this relationship (3) it may be seen that the current/voltage curve of the photodiode does not pass through the point (0, 0). This deviation from the point (0, 0) is the reason the temperature drift effect is seen, because when the current is zero in the photodiode, corresponding to darkness, the voltage across the photodiode is not zero.

The voltage across the photodiode in solar-cell mode may be described by relationship (4) below.

$${V}_{D} = {V}_{t} log ( \frac{{I}_{λ} + {I}_{S} {e}^{- \frac{{V}_{AB}}{{V}_{t}}}}{{I}_{S}} ) \qquad ( 4 )$$

It may be seen that reverse biasing the n-doped junction 20 allows a substantially logarithmic variation to be maintained even when the current I_{S} is high, because the exponential term dependent on −V_{AB}/Vₜ is negligible.

The variation of the current Is with temperature nevertheless leads in this case to a voltage drift when the photodiode is in the dark, which it is possible to correct as described below.

When the photodiode PD is associated with a reset transistor 10, the photodiode varies from an initial voltage, denoted V_{D0}.

The simple equivalent circuit illustrated in FIG. 10 may be used to model the dynamic behavior of the photodiode after the reset operation. Analysis of this equivalent circuit allows a differential equation (5) to be derived, the solution of which gives the voltage V_{D} of the photodiode after an exposure time t.

$${V}_{D} = {V}_{T} ln \frac{{I}_{λ} + {I}_{AB}}{[ ( {I}_{λ} + {I}_{AB} ) {e}^{- \frac{{V}_{D 0}}{{V}_{T}}} - {I}_{s} ] {e}^{- \frac{( {I}_{λ} + {I}_{AB} ) t}{{V}_{T} {C}_{D}}} + {I}_{s}} \qquad ( 5 )$$

In this equation. I_{AB}=Iₛ exp (−V_{AB}/Vₜ), V_{DO} is the initial voltage across the photodiode and C_{D} the capacitance of the photodiode, the other terms having the same meaning as in equation (4).

In an image sensor, exposure time is often set to a value lower than or equal to the capture period, which is constant.

If the voltage across the photodiode at the end of exposure is plotted as a function of the level of illumination falling on the photodiode, a complex response is obtained, as FIG. 8 shows, for various temperature levels and currents I_{S}.

At high light flux, the response is strictly logarithmic, but at low flux, the response may be linear at low temperature, because the parasitic capacitance of the photodiode must be recharged after the reset operation.

In comparison, with a photodiode in solar-cell mode without the nearby reverse-biased junction 20, the photoelectric response rapidly collapses with temperature. It is impossible in this case to restore the loss of sensitivity via subsequent processing.

From equation (5) it may be seen that if the initial voltage V_{D0} of the photodiode in solar-cell mode is set to a positive value, i.e. if the photodiode is forward biased during the reset phase instead of being short-circuited, the response becomes logarithmic over the entire temperature range. The effect of temperature on the response may then be summed up as a simple shift, as illustrated in FIG. 9, in which the variation of voltage as a function of illumination has been shown for a temperature range extending from −20° C. to 90° C.

It is difficult to reset a forward-biased photodiode with a MOS transistor, because in this case the source and drain of the reset transistor are also forward biased. These forward-bias junctions inject charge into the substrate that is of the same nature as the photoelectric charge, thereby preventing correct operation of the photodiode in the image sensor.

A capacitance 40 may be used to inject a charge into the photodiode, in order that it be forward biased after the reset transistor has been opened.

The capacitance 40 may be a parasitic capacitance of the reset transistor 10 as illustrated in FIG. 1, or a specific capacitance as illustrated in FIG. 4. The initial forward bias voltage V_{D0} applied to the photodiode via this capacitance is for example 0.15 V.

The value of the capacitance is high enough to obtain the sought-after logarithmic response at low temperatures.

For example, it is sought to obtain at T=−15° C. less than 1% dispersion in the response with respect to that at 25° C. Here, dispersion is defined as the relative deviation between the response curves.

Moreover, the optical sensor according to the invention advantageously includes one or more reference pixels that are protected from the incident light and that serve to generate a reference voltage allowing the temperature shift to be compensated for, and thus a signal that is both logarithmic and independent of temperature over a wide range may be obtained.

The one or more reference pixels are masked by a metal layer forming a screen with respect to the incident light; however, in contrast to known solutions, predefined reference illumination conditions are simulated therein.

If this reference illumination level is set high enough, it is easily possible to attenuate, or even suppress, the effect of leakage of light through the optical mask using a CMOS production process.

For example, if a metal layer allows an attenuation factor of 2000 to be achieved and if the sensitivity threshold of a logarithmic pixel is 0.01 lux, the maximum tolerable illumination of a reference pixel placed in the dark is 20 lux, this being very low.

With the proposed solution, if the reference illumination is set to 10,000 lux, even if the reference pixel receives 200,000 lux, there is only a 1% variation in the reference level.

If necessary, it is possible to apply a plurality of metal layers to the one or more reference pixels for even greater precision. Generally, precision increases with the electronically simulated level of illumination.

To simulate this level of illumination, it is possible to generate a current simulating equivalent illumination conditions, and therefore a current that flows in the same direction as that generated by the operation, in solar-cell mode, of the photodiode, using a voltage source 30 connected by an electrical resistance 31 to the photodiode PD, as illustrated in FIG. 5. In the example considered, this voltage source is negative and the choice of the voltage of the voltage source 30 and the choice of the value of the resistance 31 allows the desired current to be obtained.

Another more advantageous solution is to use a voltage ramp connected by way of a capacitance 33 to the cathode of the photodiode, as illustrated in FIG. 6. The current simulating the illumination conditions may then be adjusted via the choice of the value of the capacitance and of the slope of the ramp.

The ramp voltage source may be specifically intended to generate the sought-after current. However, it may be advantageous to exploit the falling front of a control signal of a transistor of the sensor, in particular the control signal RST of the reset transistor, as illustrated in FIG. 7. This signal RST is triggered before each exposure cycle of the photodiode PD.

FIGS. 11 and 12 show two examples of sensors according to the invention, in which the junction 20 is formed by a diffusion in the substrate 11 that extends under the junctions of the photodiodes PD.

In the example of FIG. 11, the junction 20 extends, for certain photodiodes PD, only thereunder, at a distance d smaller than the diffusion length L, thereby allowing a dense implantation to be preserved.

In the example in FIG. 12, the diffusion serving to form the junction extends both laterally on either side of each photodiode PD, and preferably also thereunder.

The diffusion for example forms cups within each of which one photodiode PD is placed.

The substrate 11 may be p-type and the junctions of the photodiodes PD and the reverse-bias junctions n-type.

The depth p of diffusion to form the reverse-biased junction is relatively large.

It is for example, in the case of a 0.18 μm technology, at least 0.5 μm. A larger depth allows more of the photoelectric charge created by long wavelength photons (>650 nm) to be absorbed.

The invention is not limited to the described examples. In particular, the n and p carrier types may be inverted.

The depth p and the distance d may vary within the sensor, being local values. The depths p and distance d may be easily determined, by scanning electron microscope.

The expression “including a” or “including an” must be understood as being synonymous with “comprising at least one”, unless otherwise specified.

1. A logarithmic-response matrix-array sensor having an extended temperature operating range, said sensor including a plurality of active pixels each defined by a photodiode operating in solar-cell mode, the photodiode being formed by a semiconductor junction in a substrate, a reverse-biased junction being present at a distance from the junction of the photodiode smaller than the diffusion length of charge carriers in the substrate, the sensor including one or more reference pixels that are used to generate a reference voltage that serves to compensate for a temperature-related shift in the response of the active pixels, this or these reference pixels being masked from incident light and placed virtually under given illumination conditions by injecting a current into the junction of the photodiode.

2. The sensor as claimed in claim 1, including a capacitance for injecting a charge into the photodiode in order to forward bias it before read-out of a voltage representative of the illumination received by the photodiode.

3. The sensor as claimed in claim 1, current being injected into the photodiode of a reference pixel through an electrical resistance that is connected to a voltage source that generates a current in the same direction as the photoelectric current generated by the photodiode.

4. The sensor as claimed in claim 1, current being injected into the photodiode of a reference pixel through a capacitance connected to a ramp voltage source that generates a current in the same direction as the photoelectric current generated by the photodiode.

5. The sensor as claimed in claim 1, the substrate being a p-type semiconductor, in particular p-type silicon, and the photodiode including an n⁺-type region.

6. The sensor as claimed in claim 1, the reverse-biased junction being generated by an n⁺-type region.

7. The sensor as claimed in claim 1, the n⁺-type region of the reverse-biased junction being defined by an n-doped well of a PMOS transistor for reading the voltage of the photodiode.

8. The sensor as claimed in claim 1, including for each pixel a transistor for resetting the photodiode, applying, when in the on state, a predefined voltage to the photodiode.

9. The sensor as claimed in claim 2, the capacitance for injecting charge into the photodiode, in order to forward bias it before read-out of the voltage, being a parasitic capacitance of the reset transistor.

10. The sensor as claimed in claim 2, the capacitance for injecting charge into the photodiode, in order to forward bias it before read-out of the voltage, being a capacitance produced specifically.

11. The sensor as claimed in claim 2, the initial bias voltage of the photodiode following the injection of charge by means of the capacitance being comprised between 0.1 and 0.2 V.

12. The sensor as claimed in claim 1, the reverse-biased junction extending under the junction of the photodiode.

13. The sensor as claimed in claim 1, the reverse-biased junction extending on at least two opposite sides on either side of the junction of the photodiode and better still all the way around the photodiode.

14. A method for operating the sensor of claim 1, including resetting the photodiode by closing a reset transistor and injecting a charge into the photodiode in order to forward bias it at the start of the phase for measuring the light received by the photodiode and obtaining a logarithmic response in a wide-temperature-range operating range.

15. The method as claimed in claim 14, the temperature range encompassing at least the range −15° C. to 60° C.

16. The method as claimed in claim 14, the voltage of the photodiode of an active pixel being corrected by the voltage read from a reference pixel, in order to generate a signal representative of the illumination received by the active pixel and independent of the temperature in the operating range.

17. The method as claimed in claim 14, current being injected into the photodiode of a reference pixel through a capacitance connected to a ramp voltage source that generates a current in the same direction as the photoelectric current generated by the photodiode, the ramp voltage consisting of the falling front of a control signal of the reset transistor.

18. The method as claimed in claim 14, the temperature range encompassing at least the range −50° C. to 100° C.
